(19) United States
(12) Patent Application Publication
(10) Pub. No.: US 2004/0177202 A1
(43) Pub. Date: Sep. 9, 2004

(54) Apparatus and method for generating hot-plug signal

(75) Inventor: Jong-Eun Won, Incheon Metropolitan-city (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 10/667,364

(22) Filed: Sep. 23, 2003

(30) Foreign Application Priority Data
Feb. 19, 2003 (KR) 2003-10382

(51) Int. Cl. H05K 7/10; G06F 13/00

(52) U.S. Cl. 710/302

(57) ABSTRACT

An apparatus and method for recognizing whether a medium is inserted into or removed from a hot-plug apparatus and generating a hot-plug signal are provided. The hot-plug signal generation apparatus includes a medium insertion unit, which receives a medium and generates a sensor signal when the medium is inserted or removed; a medium control unit which controls the received medium and generates the hot-plug signal; and a switch which outputs the hot-plug signal in response to the sensor signal generated by the medium insertion unit.

### BACKGROUND OF THE INVENTION

This application claims priority from Korean Patent Application No. 10-2003-0010382, filed on Feb. 19, 2003, in the Korean Intellectual Property Office, the disclosure of which is incorporated herein in its entirety by reference.

1. Field of the Invention

The present invention relates to a hot-plug apparatus, and more particularly, to an apparatus and method for recognizing insertion or removal of a medium with respect to a hot-plug apparatus to generate a hot-plug signal.

2. Description of the Related Art

With the introduction of Microsoft's Windows 95 in 1995, a plug and play (PnP) function which automatically recognizes extended devices and automatically installs drivers first appeared. This function has been very well received by users, but it is only supported by some devices that plug into a port of a PC (personal computer). For this reason, a new technology that extends this plug and play function to all peripheral devices of a computer has appeared. As one means for this, USB (Universal Serial Bus) has been developed.

Generally, when connecting and installing a peripheral device to a PC, a user should designate what the peripheral device is and also install required software (driver) of the peripheral device. The plug and play function performs these tasks automatically.

Some home appliances have external devices that can be attached/detached. However, in a PC, there are cases when the attachment/detachment of external devices is impossible. For example, if a keyboard or a mouse is connected to a PC after the PC has been turned on, the keyboard or mouse will not operate. However, USB enables a hot-plug-in and hot-plug-out after a PC has been turned on. That is, the hot-plug function enables automatic recognition of a medium. This function also enables different devices to be connected and used when needed. For example, a keyboard and a mouse are connected to a PC for general computing purposes and can be replaced while the PC is turned on by a game pad and a joystick for entertainment purposes. Therefore, unnecessary peripheral devices can be kept out of the way, thereby making efficient use of space.

In Microsoft's Windows XP, when a printer or a USB device, etc., is hot-plugged-in, the device is automatically recognized and a user is notified of this recognition. However, in order to be recognized, hot-plugged-in peripheral devices must support the plug and play function. Hence, since most recent peripheral devices support plug and play, recognition and installation operations are generally performed without difficulty in Windows XP.

USB was designed as a communication means for connecting a PC with peripheral devices. Comparing USB with SCSI (Small Computer System Interface), a type of external bus currently in widespread use, USB cables are thinner and lighter and have smaller connectors. As a result, production cost can be reduced. Another characteristic of USB is the plug and play function. Through the plug and play function, peripheral devices are connected easily to the PC without particular effort.

A memory stick device is a memory platform that is about the size of a typical stick of chewing gum, designed by Sony Corp., and can be used commonly in various electronic devices including PCs, digital cameras, personal digital assistants (PDAs), mobile phones, portable audio players, AIBO robot dogs, etc. Considering that Multimedia Cards (MMCs) are small, Sony Corp. developed Memory Stick Duo, which is half the size of the memory stick device and comparable in size to the MMC card. The memory stick device is also provided in a MagicGate format which has a built-in contents copy prevention function such as SD (Secure Digital).

FIG. 1 is a block diagram of a conventional memory stick device.

As shown in FIG. 1, a memory stick reader 100 includes a memory stick socket 110 and a memory stick controller 120. The memory stick reader 100 is connected with a host PC 130 through a USB cable. When the memory stick reader 100 is first connected to the host PC 130, the host PC 130 recognizes the connected memory stick reader 100 as a mobile storage device and performs corresponding operations, such as installing a driver or assigning a name to an accessible drive. That is, when the memory stick reader 100 is first connected to the PC, it is recognized through a plug and play function.

The above-described conventional operation method has several problems as follows. First, the host PC 130 cannot recognize when a memory stick 140 is actually inserted into or removed from the memory stick reader 100. Because the memory stick reader 100 is automatically recognized as a mobile storage device the moment it is connected to the host PC 130, the host PC 130 cannot recognize whether the memory stick 140 has actually been inserted into the reader 100.

Also, an icon representing the memory stick 140 is displayed in an operating system such as Windows, but if a user tries to access the memory stick 140 when not actually inserted into the reader 100, an error is generated. This error is even more troublesome when the operating system is not Windows but Linux. In the Linux operating system, because there is no medium inserted, an error is output and insertion (or removal) is not performed automatically. Accordingly, the memory stick reader should always be connected after inserting the memory device and disconnected before removing the memory stick. This is very inconvenient.

In this connection, U.S. Pat. No. 6,131,134 describes a technology related to a hot plug and play converter of a USB interface. However, unlike the present invention, the above-mentioned patent discloses a method of converting a non-PnP (non-Plug-and-Play) interface, not a PnP device, into a USB interface.

### SUMMARY OF THE INVENTION

The present invention provides an apparatus and method for generating a hot-plug signal, which automatically recognize a memory stick or other medium when the memory stick or other medium is actually inserted into or removed from a hot-plug device, and not when the hot-plug device is connected, thereby allowing a user to access the medium.

According to an exemplary aspect of the present invention, there is provided an apparatus for generating a hot-plug signal comprising: a medium insertion/removal sensing unit which senses when a medium is inserted or removed; and a hot-plug signal control unit which outputs a hot-plug signal when the medium insertion/removal sensing unit senses that the medium is inserted or removed.

According to another exemplary aspect of the present invention, an apparatus for generating a hot-plug signal comprises: a medium insertion unit, which receives a medium and generates a sensor signal when the medium is inserted or removed; a medium control unit which controls the received medium and generates a hot-plug signal; and a switch which outputs the hot-plug signal in response to the sensor signal generated by the medium insertion unit.

Also, the hot-plug signal is preferably, but not necessarily, a D+ or D− signal defined in a USB standard.

According to still another exemplary aspect of the present invention, there is provided a method for generating a hot-plug signal comprising: (a) sensing when a medium is inserted or removed; and (b) controlling a hot-plug signal to be output or not so that the hot-plug signal is output when the medium is inserted or removed.

According to yet another exemplary aspect of the present invention, a method for generating a hot-plug signal comprises: (a) generating a sensor signal when a medium is inserted or removed; (b) controlling the medium and generating a hot-plug signal, and (c) controlling a hot-plug signal to be output in response to the sensor signal.

According to a further exemplary aspect of the present invention, there is provided a computer readable medium having embodied thereon a computer program for the aforementioned method(s).

### BRIEF DESCRIPTION OF THE DRAWINGS

The above and other features and advantages of the present invention will become more apparent by describing in detail various exemplary embodiments thereof with reference to the attached drawings in which:

FIG. 1 is a block diagram of a conventional memory stick device;

FIG. 2 is a block diagram of a memory stick device according to an embodiment of the present invention; and

FIG. 3 is a flow chart illustrating a method for generating a hot-plug signal according to an embodiment of the present invention.

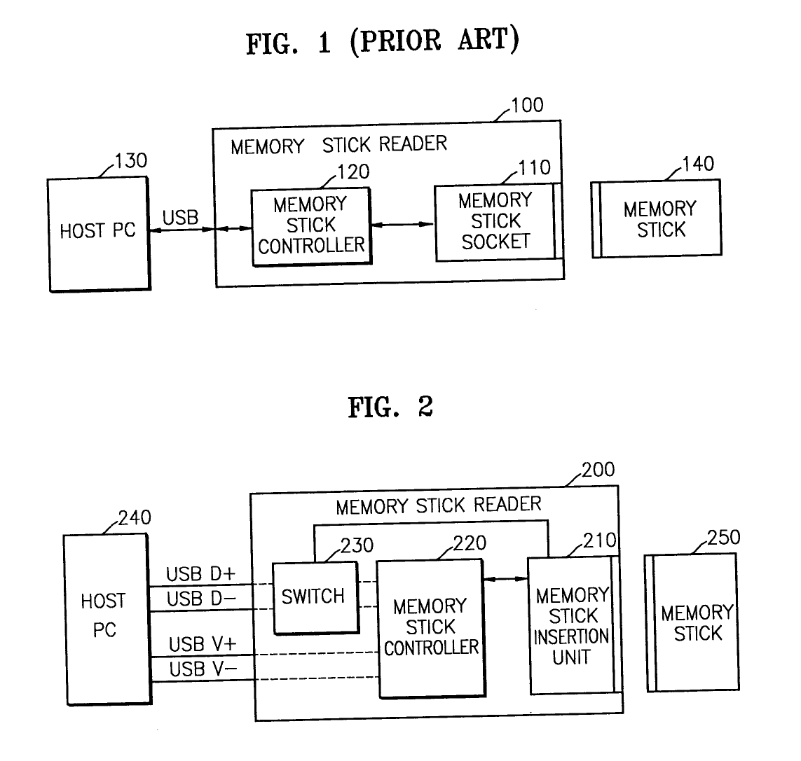

### DETAILED DESCRIPTION OF THE INVENTION

Hereinafter, illustrative, non-limiting embodiments of the present invention will be described in detail with reference to the appended drawings.

FIG. 2 is a block diagram of a memory stick device according to an embodiment of the present invention.

Referring to FIG. 2, a memory stick reader 200 includes a memory stick insertion unit 210, a memory stick control unit 220 and a switch 230.

The memory stick insertion unit 210, which is also referred to as a medium insertion/removal sensing unit, is a portion into which a memory stick 250 is inserted and has signal lines that are determined according to an interface with the memory stick 250. For example, a pin number five of the memory stick 250 and a corresponding pin of the interface of the memory stick insertion unit 210 become low upon insertion of the memory stick 250. This connects the pin number five of the memory stick 250 to the switch 230 to switch a D+ or D− signal of USB, thus generating a hot-plug signal. This uses a property of the memory stick 250 and the fact that a signal recognizing devices in USB is the D+ or D− signal.

When the memory stick 250 is inserted, a hot-plug-in operation is performed in the sequence of a low output of the pin number five of the interface of the memory stick 250, an ON state of the switch 230, and a plug-in of the USB device. When the memory stick 250 is removed, a hot-plug-out operation is performed in the sequence of a high output of the pin number five of the interface of the memory stick 250, an OFF state of the switch 230, and a plug-out of the USB device.

Through the steps described above, it is recognized that the USB device (memory stick reader) is connected when the memory stick 250 is inserted, not when the memory stick reader 200 is connected, and accordingly it is possible to perform a required operation such as loading a driver. Likewise, when the memory stick 250 is removed, it is recognized that the USB device (memory stick reader) is disconnected, and accordingly it is possible to perform a required operation such as deleting the driver. By performing the hot-plug-in/hot-plug-out through this method, it is also possible to automatically execute contents or programs stored in the memory stick 250.

In a case of a general external medium other than the memory stick, an apparatus for generating a hot-plug signal may include a medium insertion/removal sensing unit and a hot-plug signal control unit, wherein the medium insertion/removal sensing unit generates a signal when it senses that the external medium is inserted or removed, and the hot-plug signal control unit controls a hot-plug signal output according to the signal generated by the medium insertion/removal sensing unit.

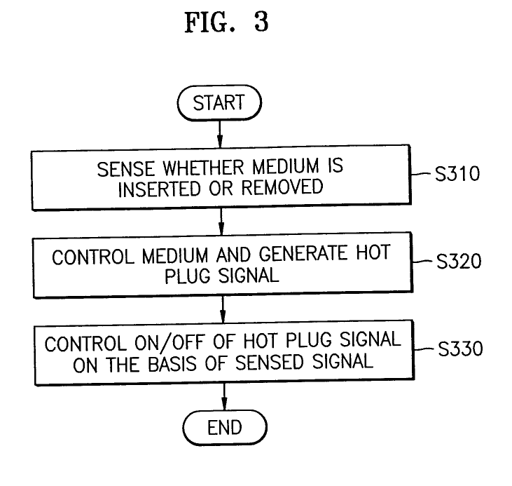

FIG. 3 is a flow chart illustrating a method for generating a hot-plug signal according to the present invention.

First, insertion or removal of an external medium is sensed (S310). That is, a sensor signal is generated upon insertion or removal of the external medium, and the sensor signal is transmitted to a switch. Here, the external medium may be a memory stick.

Then, the external medium is controlled and a hot-plug signal is generated (S320). The hot-plug signal may be a D+ or D− signal defined in a USB standard. Finally, an on/off operation of the hot-plug signal output is controlled in response to the sensor signal generated upon insertion/removal of the external medium (S330).

The present invention can also be implemented as a computer readable code stored on a computer readable medium. The computer readable medium may be, for example, ROM, RAM, CD-ROM, a magnetic tape, a floppy disc, an optical data storage medium, etc. Also, the computer readable medium may be implemented in the form of carrier waves (e.g., transmission through the Internet). Also, the computer readable medium may be allocated to computer systems connected to each other through a network so that the computer readable code can be stored and executed in a dispersed form.

As described above, the present invention enables general users as well as PC users to use external devices easily and conveniently by recognizing insertion/removal of the external devices and generating a hot-plug signal.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An apparatus for generating a hot-plug signal comprising:
a medium insertion/removal sensing unit which senses when a medium is inserted or removed; and
a hot-plug signal control unit which outputs a hot-plug signal when the medium insertion/removal sensing unit senses that the medium is inserted or removed.

2. An apparatus for generating a hot-plug signal comprising:
a medium insertion unit, which receives a medium and generates a sensor signal when the medium is inserted or removed;
a medium control unit which controls the received medium and generates a hot-plug signal; and
a switch which outputs the hot-plug signal in response to the sensor signal generated by the medium insertion unit.

3. The apparatus of claim 1, wherein the medium is a memory stick.

4. The apparatus of claim 2, wherein the medium is a memory stick.

5. The apparatus of claim 2, wherein the medium insertion unit transmits the sensor signal to the switch.

6. The apparatus of claim 1, wherein the hot-plug signal is a D+ or D− signal defined in a USB standard.

7. The apparatus of claim 2, wherein the hot-plug signal is a D+ or D− signal defined in a USB standard.

8. A method for generating a hot-plug signal comprising:
(a) sensing when a medium is inserted or removed; and
(b) controlling a hot-plug signal output so that the hot-plug signal is output when the medium is inserted or removed.

9. A method for generating a hot-plug signal comprising:
(a) generating a sensor signal when a medium is inserted or removed;
(b) controlling the medium and generating a hot-plug signal; and
(c) controlling the hot-plug signal to be output in response to the sensor signal.

10. The method of claim 8, wherein the medium is a memory stick.

11. The method of claim 9, wherein the medium is a memory stick.

12. The method of claim 9, wherein in step (a), the sensor signal generated upon the insertion/removal of the medium is transferred to a switch for outputting the hot-plug signal.

13. The method of claim 8, wherein the hot-plug signal is a D+ or D− signal defined in a USB standard.

14. The method of claim 9, wherein the hot-plug signal is a D+ or D− signal defined in a USB standard.

15. A computer readable medium storing a computer program for executing a hot-plug signal generation method, the hot-plug signal generation method comprising:
(a) sensing when a medium is inserted or removed; and
(b) controlling a hot-plug signal output so that the hot-plug signal is output when the medium is inserted or removed.

16. A computer readable medium storing a computer program for executing a hot-plug signal generation method, the hot-plug signal generation method comprising:
(a) generating a sensor signal by sensing whether a medium is inserted or removed;
(b) controlling the medium and generating the hot-plug signal; and
(c) controlling the hot-plug signal to be output in response to the sensor signal.
